(19) United States
(12) Patent Application Publication
(10) Pub. No.: US 2016/0276501 A1
(43) Pub. Date: Sep. 22, 2016

(54) SOLAR PANEL CONVERTER LAYER

(71) Applicant: Bright New World AB, Lund (SE)

(72) Inventors: Ola WASSVIK, Moheda (SE); Håkan BERGSTRÖM, Torna-Hallestad (SE); Mats-Petter WALLANDER, Lund (SE); Thomas CRAVEN-BARTLE, Sodra Sandby (SE)

(21) Appl. No.: 14/658,772

(22) Filed: Mar. 16, 2015

(51) Int. Cl. H01L 31/0232; H01L 31/042; H01L 31/054

(52) U.S. Cl. CPC H01L 31/02322; H01L 31/0549; H01L 31/042

(57) ABSTRACT

A light conversion sheet for application on top of a solar cell panel. The light conversion sheet has a front surface configured to face the sun and a back surface configured to face a solar cell, and comprises a photo luminescent layer, configured to emit light at a photo luminescent wavelength upon absorption of light of shorter wavelengths; and a spectrally selective mirror arranged between the photo luminescent layer and the front surface, configured to reflect light of the photo luminescent wavelength.

### TECHNICAL FIELD

The invention relates generally to solar panels, configured to convert incident electromagnetic energy into electrical energy. In particular, the invention relates to improving existing solar panels so as to increase efficiency at low cost.

### BACKGROUND

Different technologies for converting solar radiation energy into other forms of useful energy have been suggested throughout the years. While various solutions for converting solar energy into thermal energy have been developed, the most challenging objective has been to convert radiation energy into electrical energy. In such a scenario, a solar panel generally refers to a photovoltaic module, including a set of photovoltaic (PV) cells, or solar cells, that generally are electrically connected.

The most prevalent material for solar panels is silicon (Si), and a typical Si PV cell is composed of a thin wafer consisting of an ultra-thin layer of phosphorus-doped (n-type) silicon on top of a thicker layer of boron-doped (p-type) silicon. An electrical field is created near the top surface of the cell where these two materials are in contact, called the p-n junction. When sunlight strikes the surface of a PV cell, this electrical field provides momentum and direction to light-stimulated charged carriers, i.e. electrons or holes, resulting in a flow of current when the solar cell is connected to an electrical load. In a single junction PV cell, only photons whose energy is equal to or greater than the band gap of the cell material can free an electron for an electric circuit. In other words, the photovoltaic response of single junction cells is limited to the portion of the sun's spectrum whose energy is above the band gap of the absorbing material, and lower-energy photons are not used. Furthermore, excessive energy above the band gap will be lost as heat.

Different solutions for targeting the problem of mismatch between the very sharp band gap absorption and the wide spectrum of the solar radiation have been suggested. For one thing, solar panels with several p-n junctions of different band gap have been provided. Such multi junction cells have primarily been developed based on thin film technology. As an example, such a cell may comprise multiple thin films, each essentially a solar cell grown on top of each other by metalorganic vapor phase epitaxy. A triple junction cell, for example, may consist of the semiconductors: GaAs, Ge, and GaInP. Each layer thus has a different band gap, which allows it to absorb electromagnetic radiation over a different portion of the spectrum.

Another solution is suggested in U.S. Pat. No. 8,664,513, in which solar modules including spectral concentrators are described. A solar module includes an active layer including a set of photovoltaic cells, and a spectral concentrator optically coupled to the active layer and including a luminescent material that exhibits photoluminescence in response to incident solar radiation with a peak emission wavelength in the near infrared range.

In spite of extensive research in the area, solar panel technology still faces the challenge of improving efficiency in terms of energy conversion, and the balance of energy gained compared to cost of development and installation. An aspect of this problem is the generation of heat in solar panels, which both means that a part of the incident radiation energy is not successfully converted into electrical energy, and which furthermore might be detrimental to the function and lifetime of the solar panel.

### SUMMARY

According to a first aspect, the invention relates to a light conversion sheet , for application on top of a solar cell panel, said light conversion sheet having a front surface configured to face the sun and a back surface configured to face a solar cell, and comprising a photo luminescent layer, configured to emit light at a photo luminescent wavelength upon absorption of light of shorter wavelengths; and a spectrally selective mirror arranged between the photo luminescent layer and the front surface, configured to reflect light of the photo luminescent wavelength.

In one embodiment, the spectrally selective mirror has a reflectivity of at least 95% at the photo luminescent wavelength.

In one embodiment, the spectrally selective mirror has a reflectivity of at least 99% at the photo luminescent wavelength.

In one embodiment, said photo luminescent layer includes quantum dots, configured to emit light at said photo luminescent wavelength.

In one embodiment, said photo luminescent wavelength is in the range of 700-1200 nm.

In one embodiment, light of said photo luminescent wavelength has an emission peak centre within +/−10 nm of 950 nm.

In one embodiment, the light conversion sheet comprises a second selective mirror, arranged between the photo luminescent layer and the back surface, configured to reflect light of shorter wavelength than the photo luminescent wavelength.

In one embodiment, the second selective mirror is substantially transmissive at the photo luminescent wavelength, and has a reflectivity of at least 90% in a range below a cut-off wavelength, which is shorter than the photo luminescent wavelength.

In one embodiment, the light conversion sheet comprises a transmissive scattering layer, arranged between the photo luminescent layer and the second selective mirror, which is diffusively transmissive to at least wavelengths shorter than the photo luminescent wavelength.

In one embodiment, the light conversion sheet comprises a reflective scattering layer covering a predetermined portion of said back surface. In one embodiment, said reflective scattering layer covers at least 25% of said back surface.

In one embodiment, said reflective scattering layer covers less than 50% of said back surface.

In one embodiment, the light conversion sheet comprises a light transmissive bulk layer between said photo luminescent layer and said back surface.

In one embodiment, said back surface is configured with a transmissive scattering surface layer.

In one embodiment, said transmissive scattering surface layer comprises at least one of a micro lens array, a diffraction grating, a prismatic structure, and an etched stochastic microstructure.

In one embodiment, said transmissive scattering surface layer has structures of feature sizes in the range of 0.5-100 μm.

In one embodiment, the light conversion sheet comprises a protective layer between the front surface and the spectrally selective mirror.

According to a second aspect, the invention relates to a solar panel comprising a solar cell having a band gap corresponding to a detection wavelength, and a light conversion sheet having a front surface configured to face the sun and a back surface configured to face the solar cell, wherein said light conversion sheet comprises a photo luminescent layer, configured to emit light at a photo luminescent wavelength upon absorption of light of shorter wavelengths; and a spectrally selective mirror arranged between the photo luminescent layer and the front surface, configured to reflect light of the photo luminescent wavelength, wherein the photo luminescent wavelength is shorter than said detection wavelength.

In one embodiment, the solar panel comprises a reflective scattering layer between the photo luminescent layer and the solar cell, covering a predetermined portion of the solar cell and having openings for passing light from the light conversion sheet to the solar cell.

In one embodiment, said reflective scattering layer covers at least 25% of the upper surface of the solar cell.

In one embodiment, said reflective scattering layer covers at least 50% of the upper surface of the solar cell.

In one embodiment, said reflective scattering layer covers between 50 and 80% of the upper surface of the solar cell.

In one embodiment, the solar cell is provided with upper connectors at its upper surface, wherein said reflective scattering layer covers and extends beyond each upper connector.

In one embodiment, high doping regions of the solar cell are present below the upper connectors, and wherein said reflective scattering layer covers each high doping region.

In one embodiment, the upper connectors cover a connector area of the upper surface of the solar cell, and wherein said predetermined portion covered by the reflective scattering layer is at least 50% larger than connector area.

In one embodiment, the solar panel comprises two or more solar cells distributed side by side, wherein said reflective scattering layer covers an area between adjacent solar cells.

According to a third aspect, the invention relates to a method for improving the efficiency of a solar panel comprising solar cells having a band gap corresponding to a detection wavelength, comprising the step of applying a light conversion sheet according to any one of the preceding embodiments with its back surface facing an upper surface of the solar panel, wherein said photo luminescent wavelength is shorter than said detection wavelength.

In one embodiment, the method comprises the step of applying an optically clear adhesive to bond the back surface of the light conversion sheet to the upper surface of the solar panel.

### BRIEF DESCRIPTION OF THE DRAWINGS

Various embodiments will be described below with reference made to the accompanying drawings, in which

FIG. 1A schematically illustrates a top planar view of a solar panel comprising a number of solar cells;

FIG. 1B illustrates a side view of the solar panel of FIG. 1A;

FIG. 2 illustrates an example of a solar panel provided with a light conversion sheet according to an embodiment;

FIG. 3 illustrates a more detailed version of an embodiment in line with FIG. 2;

FIG. 4A shows an example of a spectrally selective mirror for use at a sun-facing side of an embodiment of a light conversion sheet;

FIG. 4B shows an example of a second selective mirror for use at a side of a light conversion sheet facing a solar cell in one embodiment;

FIG. 5 schematically illustrates a light conversion sheet acting as a converter add-on, joined with a solar cell;

FIG. 6 illustrates another embodiment of a light conversion sheet joined with a solar cell;

FIG. 7 illustrates yet another embodiment of a light conversion sheet joined with a solar cell; and

FIG. 8 illustrates a planar view of a solar panel according to one embodiment.

### DETAILED DESCRIPTION OF EMBODIMENTS

Various aspects of the invention will be described below with respect to exemplary embodiments. Furthermore, alternative solutions of individual elements and configurations of described embodiments will be outlined. It will thus be evident to the skilled reader that the given embodiments may be realized in many alternative ways other than those specifically given.

FIG. 1A illustrates a top planar view of a state of the art solar panel 1, comprising a plurality of solar cells 2. The solar cells 2 may be of different type, but the most common type on the market is based on a single junction silicon cell 2, having a band gap which corresponds to a certain detection wavelength λ. Each cell 2 is typically made from a Si wafer, though other types of material are also used in the art, such as GaAs. Each cell is provided with an electrode structure. On the back side of the cell 2, the electrode may have any shape, and may comprise a conductive coating (not shown) covering part of or the entire back side. On the front side of the cell 2, a connector grid is normally applied, as illustrated in the drawing of FIG. 1A. Alternatively, a transparent top electrode structure may be used, such as ITO.

FIG. 1B shows the solar panel 1 of FIG. 1A from the side, though not to scale of any realistic embodiment. This drawing shows how adjacent cells 2 may be serially connected by means of connectors 3. Normally a protective cover 4 of e.g. glass is provided to protect the cells 2, and an upper surface 5 of the protective cover 4 thus forms the outer surface of the panel 1, and may be provided with an AR coating.

A known problem related to standard solar panels is that light of shorter wavelengths than the detection wavelength λ_{C} are not efficiently converted into electrical energy. The excessive energy of an incident photon absorbed in the cell 2, exceeding the band gap, will typically be lost as heat. Not only does this result in energy loss, but the effect of the heating may also damage the solar cells 2.

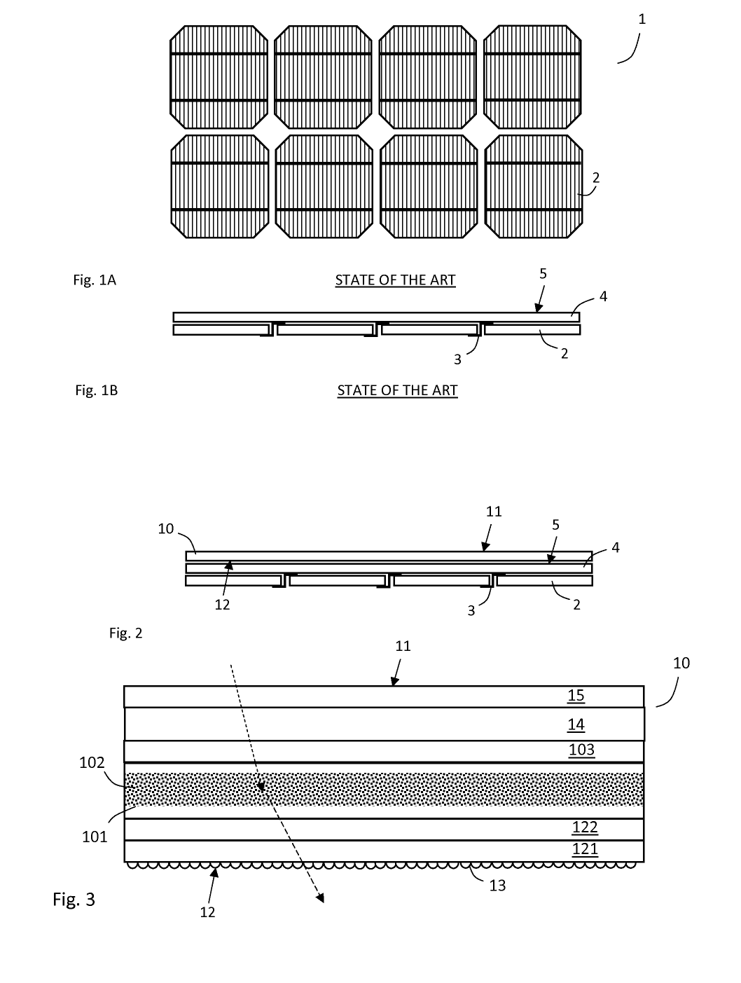

FIG. 2 illustrates an embodiment configured to alleviate this problem. In this embodiment, a light conversion sheet 10 is placed on top of a solar cell panel 1. The light conversion sheet 10 has a front surface 11 configured to face the sun, and a back surface 12 facing the solar cells 2. As will be explained, a technical effect of the light conversion sheet 10 is that it will lead to improved energy conversion efficiency of the aggregate solar panel. Furthermore, this benefit is obtained at a low installation cost, since the light conversion sheet is not electrically coupled to the solar panel 1.

FIG. 3 shows an embodiment of the light conversion sheet 10. Initially it may be noted that the drawing is schematic, and not to scale. Moreover, several different functional layers are indicated, though not all of those layers need to be included in all embodiments. FIG. 3 shows a sectional view of a part of the light conversion sheet 10. As understood from FIG. 2, the light conversion sheet 10 is configured for use together with a solar cell, but for the sake of simplicity no solar cell is depicted in FIG. 3. The light conversion sheet 10 is configured to face the sun with its upper surface 11, through which incident light will be received. Such incident light, indicated by the dashed arrows, will hit a photo luminescent layer 101. The photo luminescent layer 101 may be configured to convert incident light of shorter wavelengths, such as from the sun or other light source, to light of at least one longer wavelength λ_{PL}. More particularly, the photo luminescent layer 101 is configured to emit light at a photo luminescent wavelength λ_{PL} upon absorption of light of shorter wavelengths. This is accomplished by means of the incorporation of a photo luminescent material 102 in a suitable carrying matrix, such as a polymer film, in the photo luminescent layer 101. The photo luminescent material 102 may be realized by means of dye, but in a preferred embodiment the photo luminescent material 102 comprises quantum dots, examples of which will be outlined in greater detail further below. The photo luminescent light will subsequently be led out from the light conversion sheet 10 through its back surface 12, for detection in a solar cell. Photo luminescent light may be emitted in different angles, with respect to the incident light. Furthermore, such photo luminescent light may be reflected or scattered in the light conversion sheet 10, such that it is directed back towards the front surface 11. However, a spectrally selective mirror 103 is arranged between the photo luminescent layer 101 and the front surface 11, configured to reflect light of the photo luminescent wavelength λ_{PL}. This way, converted light emitted from the photo luminescent layer 101 is trapped in the light conversion sheet 10, and only mainly allowed to exit through the back surface 12.

A surface layer 13 in the form of a texture or grating may be arranged at the bottom surface 12 of the light conversion sheet 10. Such an embodiment has the effect of minimizing the risk that light in certain angles of incidence are trapped by TIR in the light conversion sheet 10. It also allows for the use of an air gap between the light conversion sheet 10 and a solar cell arranged adjacent the back surface 12, as will be discussed below. Examples of means for providing a textured surface layer 13 include a structured surface, rough surface, a diffraction grating, or a micro lens array.

According to one aspect, the invention targets the need for a concept for a spectrally concentrating and spectrally trapping solar cell design, suited for cost-effective high-volume manufacturing. This object is achieved by solving a number of issues, as described herein, and will be described with reference to the non-limiting embodiment of the drawings. In addition to the general structural and functional description given above, further details of various embodiments will now be described, initially with reference to FIG. 3.

The photo luminescent layer 101 is preferably configured to emit fluorescent light, or in other words down-convert light incident upon it into light, of one or more wavelengths λ_{PL}, adapted for absorption by solar cells for conversion into electrical energy. In one embodiment, the light conversion sheet 10 is configured to operate together with single junction solar cells, having a band gap corresponding to a detection wavelength λ_{C}. In such an embodiment, the photo luminescent layer 101 is preferably configured to emit light with a single peak of emission, i.e. light of one wavelength λ_{PL}≦λ_{C}, i.e. of corresponding or larger energy than the band gap of that single junction. In a variant of this embodiment, the light conversion sheet 10 is configured to operate together with multi junction solar cells. In such an embodiment, the photo luminescent layer 101 is preferably configured to emit light at different wavelengths, each with a peak of emission λ_{PLn} corresponding to a band gap λ_{Cn} of the junctions of the solar cells.

In a preferred embodiment, efficient spectral concentration, or light conversion, is realized by means of including a layer of quantum dots (QDs) 102 in the photo luminescent layer 101, due to their stable nature as compared to dyes. QDs are well described in the art of nanophysics, and so are several known properties. One specific optical feature of QDs is the emission of photons under excitation, and the wavelength of the emitted light. One photon absorbed by a QD will yield luminescence, in terms of fluorescence. Due to the quantum confinement effect, QDs of the same material, but with different sizes, can emit light of different wavelengths. The larger the dot, the lower the energy of the emitted light. As indicated by its name, a QD is a nano-sized crystal e.g. made of semiconductor materials, small enough to display quantum mechanical properties. Typical QDs may be made from binary alloys such as cadmium selenide, cadmium sulfide, indium arsenide, and indium phosphide, or made from ternary alloys such as cadmium selenide sulfide. Some QDs may also comprise small regions of one material buried in another material with a larger band gap, so-called core-shell structures, e.g. with cadmium selenide in the core and zinc sulfide in the shell.

One of the two main advantages with modern QD's, besides the fact that down-conversion can be utilized to trap photons with a spectral mirror is the high External Quantum Efficiency (EQE); in some cases >95% energy conversion have been achieved. The physical mechanisms behind this high EQE involves multi exciton/photon generation processes wherein one absorbed photon of energy E may be converted into more than one luminescent photon, e.g. two with energy 0.95 *E/2, see e.g. Chapters 9 & 103 of Quantum Dot Solar Cells Eds. Wu & Wang by Springer.

The QDs 102 may be of core, shell/core or giant shell/core type. In a preferred embodiment, the QDs 102 are of a shell/core structure, which are suitable for infusion in a carrier material, e.g. a PET film, and still keep its high quantum efficiency.

Alternatives to the carrier, or matrix, material may include PMMA (para-Methoxy-N-methylamphetamine), epoxy resins etc. For stability reasons, the luminescent material 102 normally needs to be well encapsulated from the environment. This can be achieved by encapsulating luminescent material 102 in a dielectric layer or polymer. Another option for the photo luminescent layer 101 is to have a diffusion barrier on each side of the layer to maintain the function of the luminescent material 102, which may be adversely affected by moisture and oxygen. The diffusion barriers can of course be put elsewhere in the stack but an advantage of putting it on the photo luminescent layer 101 itself is that the photo luminescent layer 101 can then be produced in one location and shipped to another place for assembly. Typical diffusion barriers can be dielectric coatings but many other options exist. As one example, PTFE (Polytetrafluoroethylene) of a suitable quality can act as a diffusion barrier, e.g. CYTOP®, which is an amorphous fluoropolymer. In one preferred embodiment the luminescent material 102 is printed onto a thin PTFE film and then coated with another layer of PTFE so that the luminescent material 102 is sealed within a PTFE structure protecting it from the environment while maintaining high optical clarity and good mechanical properties. The general function of incorporation of QDs 102 suspended in a polymer film has been suggested by Nanosys Inc, together with 3M, though for a quite different application. They provide a QD film (QDEF—Quantum Dot Enhancement Film) which replaces a traditional diffuser film of a backlight unit. In their solution, blue LEDs are used to inject light into a backlight light guide, and part of the blue light is then shifted to emit green and red in the QDEF to provide tri-chromatic white light.

In the embodiments disclosed herein, such as the embodiment of FIG. 3, the QDs 102 may e.g. be made of PbS or PbSe, configured in sizes to emit at a suitable wavelength λ_{PL} with respect to a predetermined solar cell type. Where more than one type of solar cells are employed, or if they comprise more than one junction, QDs of different sizes may be included in the luminescent material 102, and potentially also of different materials. Going forward, reference will mainly be made to embodiments configured for use with single junction solar cells, and hence a single peak emission wavelength λ_{PL} for the photo luminescence.

As mentioned, the luminescent material 102 of the photo luminescent layer 101 is configured to emit fluorescent light of an energy that is greater than the band gap of a predetermined solar cell type. Preferably, the QDs 102 of the photo luminescent layer 101 are configured to emit light at a peak wavelength λ_{PL} in the near infrared region (NIR). In one non-limiting embodiment, the light conversion sheet 10 is configured to operate with single junction Si cells with a band gap corresponding to a wavelength λ_{C} of about 1.1 μm. In a preferred embodiment, the photo luminescent layer 101 is configured to emit light at an emission peak of 950 nm. As an example, Evident Technologies provide PbS QDs with such an emission peak, and FWHM of less than 150 nm.

With reference to FIG. 3, the light conversion sheet 10 comprises an upper reflective layer 103, which acts as a spectrally selective mirror, configured to reflect light emitted from the luminescent material 102 of the photo luminescent layer 101 and to allow light with shorter wavelengths to pass. Incident solar light passes through the spectrally selective mirror 103, typically a multi-layer optical film, and then most of the light which has higher energy than the photo luminescence wavelength will be converted to light of λ_{PL} in the NIR region by the QDs 102. Light of wavelengths shorter than λ_{C}, the detection wavelength of solar cells arranged under the light conversion sheet 10 may theoretically be absorbed by such solar cells, and the spectrally selective mirror 103 is therefore preferably transparent to such light, i.e. to light of λ≦λ_{C}. At wavelengths towards the UV, each photon is highly energetic, but they are also scarce, since the sun acts as a block body radiator from which there is little emission in this part of the spectrum. The spectrally selective mirror 103 may therefore have a limited degree of transparency below the visible wavelength range. Light of wavelengths between λ_{PL} and λ_{C} will not be absorbed by the photo luminescent layer 101, but may be absorbed in by the aforementioned solar cells, and the spectrally selective mirror 103 may therefore be transmissive also to such light. However, dependent on inter alia how narrow the photo luminescence emission peak is, how close λ_{PL} is to λ_{C}, and how much the reflectivity varies dependent on angle of incidence, the spectrally selective mirror 103 may in certain embodiments be configured to be substantially reflective to light in that range. Light of wavelengths longer than λ_{C} will not be absorbed in the cells 21, and whether or not the spectrally selective mirror 103 is made reflective or transparent in this region may be determined based on other factors. For the specific peak wavelength of luminescence λ_{PL}, though, the spectrally selective mirror 103 is preferably highly reflective. This way, substantially all light emitted by fluorescence in the photo luminescent layer 101 directed, scattered or reflected upwards against the spectrally selective mirror 103, will be reflected back. Also, as noted above, by carefully designing the luminescent material 102 of the photo luminescent layer 101, and the spectrally selective mirror 103, to be optimized for a wavelength of 950 nm, very little light of the useful part of the solar spectrum is prevented from entering the panel. It may be noted that the cut-on/cut-off optimum of the spectrally selective mirror 103 has a complex dependence of all components in the light conversion sheet 10 as well as on the sun spectrum, and the inclination of the panel 1 towards the sun.

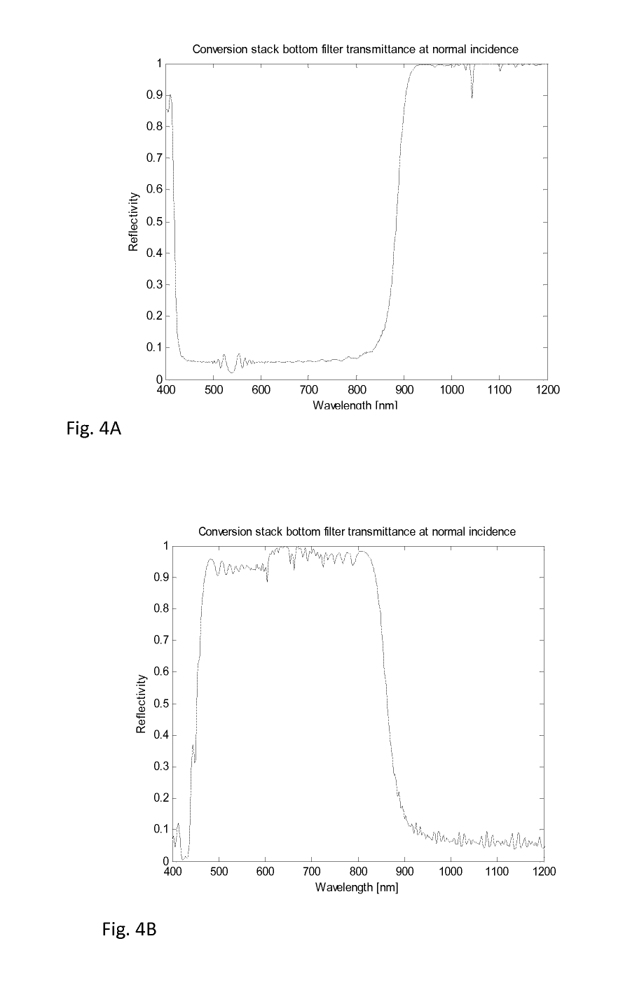

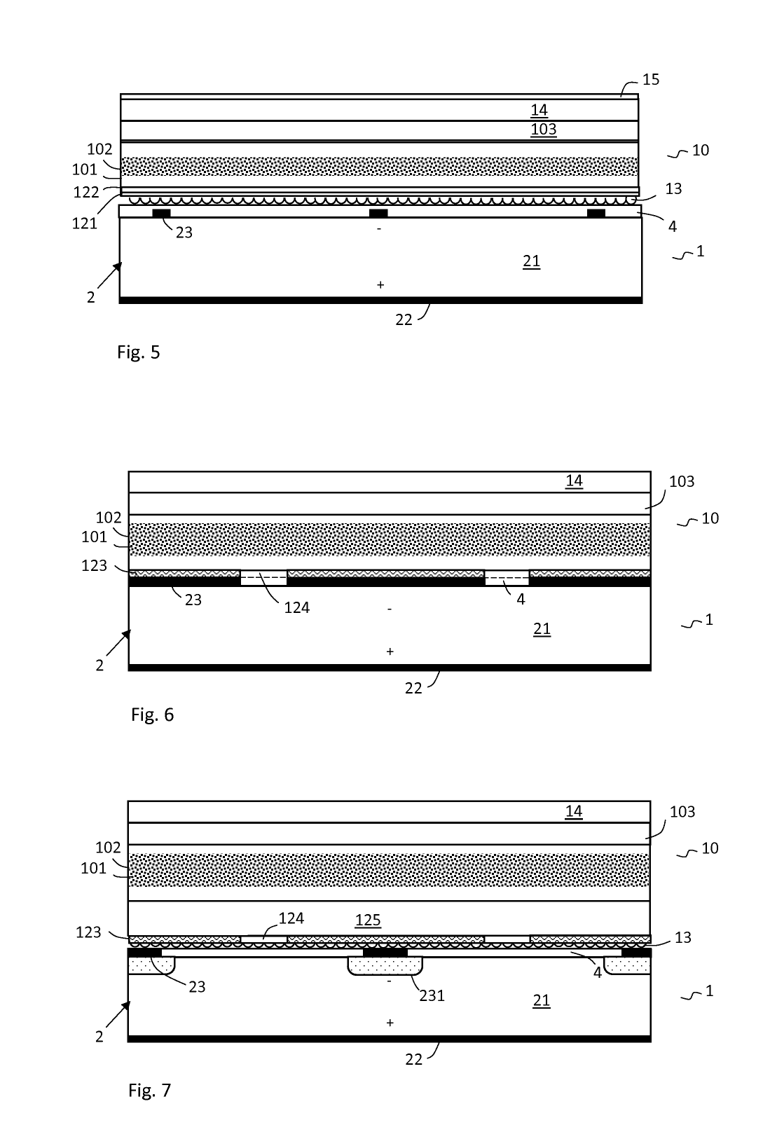

Preferably, the spectrally selective mirror 103 is optically matched to the photo luminescent layer 101. This way, Fresnel losses are minimized. Furthermore, the spectrally selective mirror 103 preferably also adheres to the photo luminescent layer 101. Examples of multi-layer optical films (MOF), usable for realizing the spectrally selective mirror 103, may include a 3M™ type GBO birefringent polymer multilayer, e.g. CMF330, or e.g. be configured as a Rugate filter, such as the design disclosed in FIG. 5 of “Combination of angular selective photonic structure and concentrating solar cell system” by Hohn et al, presented at the 27^{th} European PV Solar Energy Conference and Exhibition, 24-28 Sep. 20103 in Frankfurt, Germany. Another example, which has been tested by the inventors, is shown in FIG. 4A. This drawing shows a reflectivity profile for a spectrally selective mirror 103 having a cut-on wavelength at 884 nm for θ=0 degree angle of incidence. The spectrum shifts towards lower wavelengths as the angle of incidence θ increases. As can be gathered from the drawing, the reflectivity of the spectrally selective mirror 103 is well over 95% at λ_{PL}=950 nm, and even over 99% at least around θ=0. However, the transmittance is over 90% in the visible range, where most of the useful solar radiation to be detected in a Si solar cell is emitted.

Reference is now made to FIG. 3 again, which shows additional layers of the light conversion sheet 10, which may be included in various embodiments. In an optimum situation, 100% conversion of incident sunlight of wavelengths shorter than λ_{PL} occurs in the photo luminescent material 102 of the photo luminescent layer 101. However, if that is not the case some light of wavelengths shorter than X_{PL} could pass to the solar cells, where it would be poorly detected with loss of energy and heating of the cells. In one embodiment, this problem may be alleviated by the addition of a second selective mirror 121 somewhere between the photo luminescent layer 101 and the back surface 12. This second selective mirror 121 preferably transmits wavelengths λ that are suitable for detection, e.g. λ_{PL}≦λ≦λ_{C}, and reflects wavelengths that are poorly detected but possible to convert in the photo luminescent layer 101, i.e. λ≦λ_{PL} In other words, light of wavelengths shorter than the peak emission of the photo luminescent material 102, that has passed unconverted through the photo luminescent material 102, will be reflected back towards the photo luminescent material 102, by means of the second selective mirror 121. This way, such reflected unconverted light gets a second chance of being converted by the photo luminescent material 102.

FIG. 4B illustrates the reflectivity profile for an example of such a second selective mirror 121, tested by the inventors, having a cut-off wavelength at 886 nm for θ=0 degree angle of incidence. Again, the spectrum tends to shift towards lower wavelengths as the angle of incidence θ increases. As can be gathered from FIG. 4B, the reflectivity of the second selective mirror 121 is substantially complementary to the spectrally selective mirror 103, and over 90% in the major part of the visible spectrum. At the photo luminescence wavelength λ_{PL}=950 nm, though, the reflectivity is very low, preferably below 10%. The illustrated embodiments of FIGS. 4A and 4B represent working solutions that have been tested to provide a clear technical effect in terms of increased conversion efficiency of a Si solar cell disposed under a light conversion sheet 10 configured accordingly. However, it shall be noted that these are still only exemplary embodiments.

Turning back to FIG. 3, it may be understood that unconverted light that is reflected in the second selective mirror 121, and which is not even converted by the photo luminescent material 102 at the second passage, will escape the stack through the front surface 11 if the only deflection of that light was caused by a specular reflection in the second selective mirror 121. However, if the reflection were non-specular, or there is an additional deflection to a specular reflection, such light has a good chance of TIR

(Total Internal Reflection) when reaching the top 11 of the stack, getting even more chances of conversion in the photo luminescent layer 101. In a preferred embodiment, a scattering layer 122 is added between the photo luminescent layer 101 and the second selective mirror 121 for this purpose. Such a scattering layer 122 may e.g. be formed by including gas bubbles, either in a separate sheet or in the lower part of the matrix material of the photo luminescent layer 101, and will act as a diffusively transmitting layer 122.

While the direction of the photo luminescence light is random in itself, it is still possible that such light is trapped by TIR on the back surface 12. In order to avoid or alleviate this problem, the back surface 12 of the light conversion sheet 10 may in various embodiments be provided with a textured surface layer 13, functioning as a scattering layer. In the embodiment of FIG. 3, this surface layer 13 is illustrated as a micro lens array. Such a micro lens array may include lenses of a wide variety of sizes and shapes, both convex and concave, spherical and aspherical. Alternative embodiments may include other structures, such as a prismatic structure 13. Such an embodiment is beneficial as flat regions may be avoided altogether. Other examples of such structures in the surface layer 13 include diffraction gratings, and etched stochastic microstructures. The feature size of the surface layer 13 may e.g. be in the range of 0.5-100μm for anyone of the aforementioned types of surface layer structures. An embodiment with a textured surface layer 13 may be configured with or without the intermediate layers 121 and 122, previously discussed with reference to this drawing.

In one embodiment, the light conversion sheet 10 may further comprise an upper protective layer 14, over the photo luminescent layer 101, and on top of the spectrally selective mirror 103. The main function of that upper protective layer 14 is to protect the sensitive lower layers from the environment. The operating conditions of a solar panel 1 can be very harsh with both high and low temperatures, UV irradiation, heavy rain, sleet, hail and sandstorms. This requires the upper protective layer 14 to have the mechanical properties to withstand all of these conditions and to be able to do so for up to 25 years. Furthermore the upper protective layer 14 needs to have high transmission in the spectrum in which the spectrally selective mirror 103 is transparent to be able to pass light through to the system below. Any material that meets these conditions can be considered for the upper protective layer 14, e.g. fluoropolymers such as PTFE.

An anti-reflective (AR) coating 15 is an optional layer that can be placed on the front surface 11 to reduce Fresnel reflections off the front surface. The AR coating 15 can be made in one single layer or multiple layers depending on the desired reduction in front reflectance, and the range of incident angles over which the cell will operate. For an embodiment in which the upper protective layer 14 is constituted of a perfluorinated polymer with a refractive index around 1.3, a very good choice of material for the AR coating would be one with refractive index around 1.15. Such a combination would reduce front reflections significantly. Other implementations of AR coatings such as quintic or simpler versions of refractive index gradient dielectric coatings may be especially well suited for roll to roll processes e.g. by simply varying the concentration of oxygen in the machine direction of an evaporation stage. The Top AR coating 15 can also act as a diffusion barrier to protect the QD material 102 from moisture and oxidation, if the photo luminescent layer 101 itself does not include this function.

The upper protective layer 14 may or may not be optically matched to the spectrally selective mirror 103. In one embodiment, the upper protective layer 14 is unattached to the spectrally selective mirror 103. This way it may be easier to replace a damaged upper protective layer to boost output. In such an embodiment also the lower surface of the upper protective 14 may be covered with an AR coating.

Various embodiment related to manufacture of a light conversion sheet 10 and assembly with a solar panel 1 will now be described. In one embodiment a multi-layer optical film (MOF) of the spectrally selective mirror 103, as well as the MOF of the second selective mirror 121 and scattering layer 122, if included, is produced roll-to-roll. Examples of such films have been provided above. Also the QD infused photo luminescent layer 101 may be produced roll-to-roll. An advantage provided with the proposed solution is that the production processes for the photo luminescent layer 101, and its related layers, including spectrally selective mirror 103 etc., can be kept completely separate from the production of the solar cells, even if they are assembled and sold together. This is of high interest since the photo luminescent layer 101 preferably includes several polymers that must be kept below a certain temperature, whereas it is desirable to be able to put the solar cells through a reflow oven during production. Another benefit is that there is no requirement for alignment between the light conversion sheet 10 and the solar cells. This simplifies the process for final assembly, regardless of whether such assembly is carried out before sale and distribution, or if the light conversion sheet 10 is attached on-site to an existing solar panel.

Thus, in one embodiment, the light conversion sheet 10 is a subassembly created separately from the solar cell with which it is subsequently joined. The AR layer 15, the upper protective layer 14, the spectrally selective mirror 103, the photo luminescent layer 101, the second selective mirror 121, the scattering layer 122, and the structured surface layer 13 may all be produced separately. Alternatively, the spectrally selective mirror 103 and the AR layer 15 can be created with the upper protective layer 14 as a base material. It is also possible to deposit the photo luminescent layer 101 directly onto the spectrally selective mirror 103. If the layers are produced separately they are typically attached to each other in a lamination process with an optically clear adhesive as form of attachment, as may the optional layers 121, 122 and 13.

In one embodiment, production of the light conversion sheet 10 may comprise the following steps.

Step 1: An AR layer 15 is added on top of an upper protective layer 14. This can be done batch-wise or roll-to-roll. As an example, if the upper protective layer 14 is a PTFE film it can be beneficial to add a single layer of refractive index between 1 and 1.3 to minimize the reflection losses.

Step 2: A spectrally selective mirror 103 is added to the bottom of the upper protective layer 14. The spectrally selective mirror 103 may be pre-produced, and joined by lamination with an Optical Clear Adhesive (OCA) to the upper protective layer. Or, optionally, the upper protective layer 14 may be used as the base for the spectrally selective mirror 103, added by means of layers provided in a batch process or in a roll-to-roll process.

Step 3: A photo luminescent layer 101 is added to the bottom of the spectrally selective mirror 103. The photo luminescent layer 101, e.g. a polymer containing QDs 102, may be pre-produced in a film. In this case they may be joined by lamination with an OCA. Or, optionally, the luminescent material 102 may be coated onto the spectrally selective mirror 103 directly, and then encapsulated for protection.

In optional steps, the bottom surface of the photo luminescent layer 101 may also be provided with additional layers, such as reflecting second selective mirror 121, and a scattering layer 122, and/or also a structured lower surface layer 13, in accordance with the previously described embodiments.

The resulting light conversion sheet 10 can be used in connection with any separate standard solar cell, having a band gap to which the light conversion sheet is configured. FIG. 5 shows such an embodiment, in which the light conversion sheet 10 is used as a converter add-on, provided on top of a solar cell 2 of a solar panel 1. With reference to FIG. 1, the solar panel 1 typically, but not necessarily, includes a plurality of solar cells 2. The light conversion sheet 10 comprises at least a selective mirror 103 and a photo luminescent layer 101, in accordance with any one of the preceding embodiments. The light conversion sheet 10 may also further include a structured surface layer 13. In a preferred embodiment, the light conversion sheet 10 comprises a reflecting second selective mirror 121 at its lower surface. In one embodiment, a scattering layer 122 is included between the photo luminescent layer 101 and the second selective mirror 121. Different embodiments of the structured lower surface layer 13 have been outlined above.

When provided as a converter add-on, the light conversion sheet 10 is provided as a separate unit suited for application on an existing solar panel 1. In the preferred example of FIG. 5, a state of the art solar cell 2 is provided. This may e.g. be a single junction silicon solar cell, comprising a Si wafer 21, a lower connector layer 22, and upper connectors 23, which may be provided in the shape of fingers and bus bars, according to the established art. Such a solar cell 2 typically has a band gap corresponding to about 1.1 μm. In accordance with one embodiment, the converter add-on layer 10 is specifically configured to be suitable for this type of solar cell 2, by means of careful selection of at least the luminescent material 102, and preferably also the selective mirrors 103 and 121. As an example, described above, the luminescent material 102 may include preferably QDs having a peak emission at about 950 nm, to which also the spectrally selective mirror 103 is adapted. In one embodiment, a structured surface 13 is provided on the back surface of the converter add-on layer 10 facing the solar cell 2. The structured surface layer 13, provides the technical effect of minimizing the risk that fluorescent light from the photo luminescent layer 101 gets caught by TIR in the converter add-on layer 10, which allows for an air interface or gap between the converter add-on layer 10 and the solar panel 1. The solar cell 2 may already be provided with a protective cover glass 4, and in such a case an OCA may optionally be provided between the cover glass 4 and converter add-on layer 10 (not shown), for the purpose of optical matching and adhesion. In such an embodiment, the structured surface layer 13 may be dispensed with, if proper index matching is possible. As an alternative to adhesion, the converter add-on layer 10 may be mechanically connected to the solar cell 81 by other means, such as by clamping in an external frame (not shown).

The wavelength conversion provided by the light conversion sheet 10 serving as an add-on, as well as the spectral trapping by means of the spectrally selective mirror(s), will lead to higher efficiency of the resulting solar panel design, and minimized generation of heat.

In one embodiment, the light conversion sheet 10 in the form of a converter add-on also includes a protective layer 14, which may be provided with an AR coating 15, as explained with reference to preceding drawings, and as shown in FIG. 5. In another embodiment, the protective layer 14 may be provided afterwards. The light conversion sheet 10 in the form of a converter add-on is preferably provided in the form of a flexible film.

FIG. 6 illustrates another embodiment, which in many aspects correspond to the embodiment of FIG. 5, wherein the same reference numerals are used to indicate corresponding features. The embodiment of FIG. 6 may be manufactured such that the conversion sheet 10 is provided as a separate converter add-on, which is subsequently applied to a solar panel 1. Alternatively, the structured layer embodiment of FIG. 6 may be built from one level and up, starting from e.g. a solar panel 1 and then applying layer by layer thereon.

In the embodiment of FIG. 6, a large part of the PV solar cell 2 is covered by an reflective scattering layer 123, e.g. comprising barium sulfide, titanium dioxide or other high reflectivity scattering material, provided at the back surface of the light conversion sheet 10. The reflective scattering layer 123 is preferably non-transparent throughout the solar spectrum (full spectrum), or preferably at least for the parts of the solar spectrum below λ_{C}. In a preferred embodiment the scattering layer 123 covers at least 25% of the upper surface of the solar cell 2, and in one embodiment up to 50%. In various embodiments the scattering layer may cover up to 80% of the sun-facing surface of the solar cell 2. In between the covered parts there are openings 124 which are free from material of the reflective scattering layer 123. This substantial coverage of the solar cell 2, stopping solar light, allows for a large portion of the incident visible light to be converted to wavelengths that are suitable for detection by the solar cell 2, i.e. wavelengths close to the band gap of the photovoltaic solar cell 2. The reason for this large portion of light conversion is that the reflective scattering layer 123 allows for a significant fraction of the incident light to be trapped in TIR within the stack and allowed to interact several times with the photo luminescent layer 102. Self-absorption in photo luminescent material 102 in the form of quantum dots penalizes the energy throughput as the amount of photo luminescent material 102 is increased. Furthermore, simply adding more material to increase the conversion rate may not be a viable option due to high material cost. Furthermore, it may be difficult to create a photo luminescent layer 101 with high concentration of photo luminescent material 102 e.g. in the form of quantum dots, due to the fact that individual PL particles may not be in close vicinity of each other without causing energy loss. This also makes it preferable to use as little PL material as possible.

In a preferred embodiment, the upper connectors 23 of the solar cell 2 are disposed underneath the reflective scattering layer 123. In the embodiment shown in

FIG. 6, substantially the entire surface covered by the reflective scattering layer 123 is occupied by large upper connectors 23, typically a metal layer of e.g. copper or silver. These large connectors have the effect of reducing the electrical resistance and thereby the losses. By covering the top of a standard PV cell it is possible to use existing production processes and very thin PV cells, even down to 0.1 mm.

In one embodiment, a filler material is applied to fill up the gap in the openings 124 between the parts of reflective scattering layer 123, between the solar cell 2 and the photo luminescent layer 101. This filler material preferably acts as an anti-reflection layer between the high refractive index of the solar cell 2 and the lower refractive index of the photo luminescent layer 101, in accordance with known principles for refractive index matching. In embodiments where a conversion sheet 10 is manufactured separately and later applied to the top surface of the solar cell 2, the solar cell 2 may already be applied with a protective transparent surface material 4. In such an embodiment, index matching shall of course be carried out with respect to such a surface material 4.

In accordance with the previously described embodiments, a selective mirror 103 is provided at the upper surface of the photo luminescent layer 101, for keeping the converted light inside the stack until it has had the chance to propagate to a point at an opening 124 where it can enter the solar cell 2 and be converted. In one variant of the embodiment of FIG. 6, a second selective mirror 121 (not shown) is provided at the lower surface of the photo luminescent layer 101, such as the mirror of FIG. 4B. If included, this second selective mirror 121 may be applied only at the openings 124, or for the purpose of ease of production throughout the conversion sheet 10, below the reflective scattering layer 123.

FIG. 7 schematically illustrates an embodiment, which incorporates many of the features of the previously disclosed embodiments, and share the same reference numerals for corresponding features. This drawing shows how a bulk layer 125 is added in the conversion sheet 10, comprising a transmissive material, e.g. silicone. This has a beneficial effect together with the reflective scattering layer 123, since it increases the lateral distance traveled between each diffuse reflection in the reflective scattering layer 123. This way, the number of interactions with the reflective scattering layer 123, the photo luminescent material 102 and the spectrally selective mirror 103 are minimized.

For the sake of clarity it should be noted that the thickness of the layers included in the embodiments are not to scale in the drawings. Rather, the bulk layer 125 may be substantially thicker than the photo luminescent layer 101 if needed. In one embodiment, in which there is a spacing x between two adjacent openings 124, the thickness of the bulk layer 125 may be in the range of x/4 to x, or even up to 2x. The bulk material may also fill out the openings 124.

FIG. 7 further illustrates the addition of a structured surface 13, similar to the corresponding feature 13 described with reference to FIGS. 3 and 5 in terms of realization and technical effect. In the embodiment of FIG. 7, though, the structured surface 13 is placed underneath the reflective scattering layer 123, and thus only has function where there are openings 124 in the reflective scattering layer 123. For the same reason, there need not be any structured surface 13 parts at all underneath the surface portions covered by the reflective scattering layer 123, but only in the openings 124.

Further, in FIG. 7, the solar cell 2 is shown to have much smaller upper connectors than the embodiment of FIG. 6. This goes to show that the increased wavelength conversion efficiency of the embodiment of FIG. 6, as caused by covering a substantial part of the lower face of the conversion layer 10 with a reflective scattering layer 123, can be obtained without combination with the additional benefits rendered by employing enlarged upper connectors 23. In fact, in one embodiment, high doping regions 231 of n++ or p++ material may be provided below the upper connectors 23, as indicated in the drawing. Such high doping regions 231 preferably extend beyond the area of the corresponding connectors 23, as shown in the drawing, and may be included for the purpose of reducing metal surface recombination rates. In accordance with this embodiment, both the connectors 23 and the high doping regions are fully covered by an even larger part of the reflective scattering layer 123, in order to reduce the probability of conversion near metals or n++/p++ areas. The reflective scattering layer 123 may have a coverage that substantially corresponds to the extension of the high doping regions 231, or alternatively extend beyond the coverage of the high doping areas 231 as in FIG. 7. It should be understood that the feature of the high doping regions 231, and the reflective scattering layer 123 covering that region, may be included in any one of the other embodiments outlined herein. It thus follows that it may be advantageous to balance the size of the upper connectors 23 and the openings 124 between the areas of reflective scattering layer 123, so as to reduce surface recombination losses while maintaining low connector 23 resistance. In addition, the benefits obtained by the bulk layer of FIG. 7 may be combined with the embodiments of the preceding drawings.

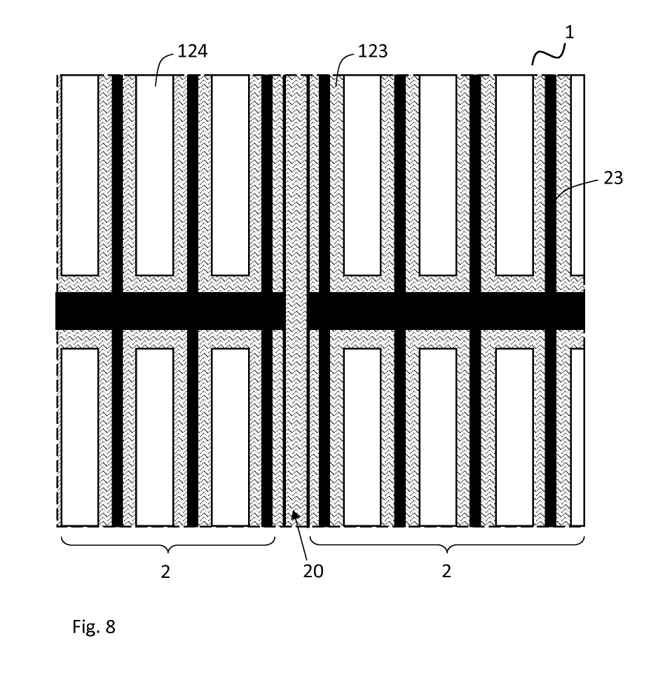

FIG. 8 schematically illustrates a planar view of an embodiment, in which a portion of a solar cell panel or module 1 is shown. In the drawing, two adjacent solar cells 2 are shown. However, it should be noted for the sake of clarity that the principles of embodiment of FIG. 8 are equally applicable to embodiments with only a single solar cell 2. Each solar cell 2 are provided with upper connectors 23, typically in the shape of fingers (running longitudinally in the drawing) with one or more connecting bus bars (running laterally). As explained with reference to FIG. 1B, adjacent cells 2 may be interconnected by means of connectors 3, but no such connectors are shown in FIG. 8. At the intersection between adjacent cells 2 a certain spacing 20 may be provided, e.g. for accommodating connectors 3.

FIG. 8 is provided to show an exemplary arrangement of the reflective scattering layer 123 with respect to the solar cells 2. FIG. 8 also shows openings 124 provided in the reflective scattering layer 123, or in other words, areas devoid of reflective scattering layer 123. For the sake of simplicity, the layers provided over the reflective scattering layer 123, such as the photo luminescent layer 101, are left out in FIG. 8. However, it should be understood that at least the photo luminescent layer 101 is preferably provided throughout the areas shown in FIG. 8, at least over the openings 124. As outlined with respect to FIG. 6 and FIG. 7, the reflective scattering layer 123 is provided over the upper connectors 23. Where high doping regions 231 (not shown in FIG. 8) are provided under the upper connectors as in FIG. 7, the scattering reflective layer 123 is provided over also such high doping regions 231. In the embodiment shown in FIG. 8, the scattering reflective layer 123 covers an area which is larger than the area covered by the upper connectors 23, and this larger area around the upper connectors 23 may substantially coincide with high doping areas 231, or be even larger as shown in FIG. 7. In addition, the reflective scattering layer 123 preferably covers a rim portion of the cells 2 and the spacing between them. In one embodiment, consistent with FIG. 7, the reflective scattering layer 123 may cover an area which is at least 50% larger than the area covered by the upper connectors 23. This way, the probability that light which enters the solar cell 2 from the light conversion sheet 10 will be absorbed in the vicinity of the upper connectors 23, in the high doping regions 231 or be lost at the edges of a cell, may be minimized, also when received at wide angles. Furthermore, photo luminescent light impinging in the spacing 20 between the solar cells 2, which simply would be lost, is reflected back into the conversion sheet 10. Such reflected light will propagate by reflection in the conversion sheet 10, and will only be let out of the conversion sheet 10 through the openings 124. An embodiment in which the reflective scattering layer 123 has a coverage that extends over and beyond the connectors 23 and high doping regions 231 to a certain degree, and potentially also over and beyond the spacing areas 20 between adjacent solar cells 2, has the benefit of easier assembly. In one embodiment, the reflective scattering layer 123 is formed at a back surface of a light conversion sheet 10, which may be provided as a larger foil for post assembly to a solar cell panel containing a plurality of solar cells distributed side by side. For such a purpose, the coverage beyond intended areas at the connectors 23 and the spacing 20 may serve to ease such assembly.

A benefit of an embodiment including the reflective scattering layer 123 according to the principles of FIGS. 7 and 8, is that improved efficiency of a solar panel may be obtain with a modification which has a comparatively low level of complexity. By covering a large portion of the solar cell 2 with the reflective scattering layer 123, the amount of photo luminescent material 102 may be minimized. A full spectrum reflective scattering layer 123 is also less complex and costly to produce than a selective mirror. In addition, the partitioning of the solar cell 2 surface into a reflective scattering layer 123 with complementary openings 124 is substantially independent on angle of incidence of light impinging thereon. It may be noted that the principles of the reflective scattering layer 123 having a coverage extending over and beyond the upper connectors 23, and also beyond high doping regions where present, may equally well be applied to the embodiment of FIG. 6, i.e. where the conversion sheet 10 is adhered to the solar cell 2, e.g. without a structured surface 13.

While much focus has been placed on the configuration at the upper surface of the solar cells 2, it may be noted that in preferred embodiments the solar cells 2 are also configured to reduce back surface recombination rates. In one embodiment, this may be accomplished by employing discrete connection points (not shown) to the Si layer 21 at the lower connector layer 22. These discrete connection points may be interconnected by means of a metal layer below a passivation layer, disposed between the discrete connection areas or points. Such an embodiment creates a back surface mirror/field, similar to what has been described in the art as the PERC concept (Passivated Emitter and Rear Cell). This type of lower connector 22 arrangement may be combined with any of the embodiments described herein.

A big problem in standard silicon solar panels is that they are heated up by the light that is not converted to electricity as well as by the resistive losses in the panel due to low voltages and high currents. In the design as proposed herein, the issue of heating from high energy photons hitting the PV cells and all energy higher than the band gap being converted to heat is solved by the photo luminescent layer 101 down shifting the majority of the incoming photons to photons that are close to the band gap of the solar cells. Thereby, the amount of energy that is converted to heat instead of electricity is lowered, and also a larger part of the available radiation energy is made available for conversion into electrical energy. The light conversion sheet 10 is preferably configured to operate with silicon solar cells, which is the most common type on the market.

While various embodiments have been described in the foregoing, the scope is defined by the appended claims.

1. A light conversion sheet, for application on top of a solar cell panel, said light conversion sheet having a front surface configured to face the sun and a back surface configured to face a solar cell, and comprising:
a photo luminescent layer, configured to emit light at a photo luminescent wavelength upon absorption of light of shorter wavelengths; and
a spectrally selective mirror arranged between the photo luminescent layer and the front surface, configured to reflect light of the photo luminescent wavelength.

2. The light conversion sheet of claim 1, wherein the spectrally selective mirror has a reflectivity of at least 95% at the photo luminescent wavelength.

3. The light conversion sheet of claim 1, wherein the spectrally selective mirror has a reflectivity of at least 99% at the photo luminescent wavelength.

4. The light conversion sheet of claim 1, wherein said photo luminescent layer includes quantum dots, configured to emit light at said photo luminescent wavelength.

5. The light conversion sheet of claim 4, wherein said photo luminescent wavelength is in the range of 700-1200 nm.

6. The light conversion sheet of claim 4, wherein light of said photo luminescent wavelength has an emission peak centre within +/−10 nm of 950 nm.

7. The light conversion sheet of claim 1, comprising a second selective mirror, arranged between the photo luminescent layer and the back surface, configured to reflect light of shorter wavelength than the photo luminescent wavelength.

8. The light conversion sheet of claim 7, wherein the second selective mirror is substantially transmissive at the photo luminescent wavelength, and has a reflectivity of at least 90% in a range below a cut-off wavelength, which is shorter than the photo luminescent wavelength.

9. The light conversion sheet of claim 7, comprising a scattering layer, arranged between the photo luminescent layer and the second selective mirror, which is diffusively transmissive to at least wavelengths shorter than the photo luminescent wavelength.

10. The light conversion sheet of claim 1, comprising a reflective scattering layer covering a predetermined portion of said back surface.

11. The light conversion sheet of claim 10, wherein said reflective scattering layer covers at least 25% of said back surface.

12. The light conversion sheet of claim 11, wherein said reflective scattering layer covers less than 50% of said back surface.

13. The light conversion sheet of claim 1, comprising a light transmissive bulk layer between said photo luminescent layer and said back surface.

14. The light conversion sheet of claim 1, wherein said back surface is configured with a transmissive scattering surface layer.

15. The light conversion sheet of claim 14, wherein said transmissive scattering surface layer comprises at least one of a micro lens array, a diffraction grating, a prismatic structure, and an etched stochastic microstructure.

16. he light conversion sheet of claim 14, wherein said transmissive scattering surface layer has structures of feature sizes in the range of 0.5-100 μm.

17. The light conversion sheet of claim 1, comprising a protective layer between the front surface and the spectrally selective mirror.

18. A solar panel comprising
a solar cell having a band gap corresponding to a detection wavelength, and
a light conversion sheet having a front surface configured to face the sun and a back surface configured to face the solar cell, wherein said light conversion sheet comprises
a photo luminescent layer, configured to emit light at a photo luminescent wavelength upon absorption of light of shorter wavelengths; and
a spectrally selective mirror arranged between the photo luminescent layer and the front surface, configured to reflect light of the photo luminescent wavelength, wherein the photo luminescent wavelength is shorter than said detection wavelength.

19. The solar panel of claim 18, comprising a reflective scattering layer between the photo luminescent layer and the solar cell, covering a predetermined portion of an upper surface of the solar cell and having openings for passing light from the light conversion sheet to the solar cell.

20. The solar panel of claim 19, wherein said reflective scattering layer covers at least 25% of the upper surface of the solar cell.

21. The solar panel of claim 19, wherein said reflective scattering layer covers at least 50% of the upper surface of the solar cell.

22. The solar panel of claim 19, wherein said reflective scattering layer covers between 50 and 80% of the upper surface of the solar cell.

23. The solar panel of claim 19, wherein the solar cell is provided with upper connectors at its upper surface, wherein said reflective scattering layer covers and extends beyond each upper connector.

24. The solar panel of claim 23, wherein high doping regions of the solar cell are present below the upper connectors, and wherein said reflective scattering layer covers each high doping region.

25. The solar panel of claim 23, wherein the upper connectors cover a connector area of the upper surface of the solar cell, and wherein said predetermined portion covered by the reflective scattering layer is at least 50% larger than the connector area.

26. The solar panel of claim 19, comprising two or more solar cells distributed side by side, wherein said reflective scattering layer covers an area between adjacent solar cells.

27. Method for improving the efficiency of a solar panel comprising solar cells having a band gap corresponding to a detection wavelength, comprising the step of applying a light conversion sheet with a back surface thereof facing an upper surface of the solar panel,
wherein the light conversion sheet includes:
a photo luminescent layer, configured to emit light at a photo luminescent wavelength upon absorption of light of shorter wavelengths; and
a spectrally selective mirror arranged between the photo luminescent layer and a front surface of the light conversion sheet, configured to reflect light of the photo luminescent wavelength, and
wherein said photo luminescent wavelength is shorter than said detection wavelength.

28. The method of claim 27, comprising the step of applying an optically clear adhesive to bond the back surface of the light conversion sheet to the upper surface of the solar panel.
